(19) United States
(12) Patent Application Publication
(10) Pub. No.: US 2004/0265733 A1
(43) Pub. Date: Dec. 30, 2004

(54) Photoacid generators

(76) Inventors: Francis M. Houlihan, Millington, NJ (US); Medhat A. Toukhy, Flemington, NJ (US); Salem K. Mullen, Hackettstown, NJ (US)

Correspondence Address: Alan Kass, Clariant Corporation, 70 Meister Avenue, Somerville, NJ, 08876, US

(21) Appl. No.: 10/609,735

(22) Filed: Jun. 30, 2003

(51) Int. Cl. G03F 7/004

(52) U.S. Cl. 430/270.1; 430/322; 430/330

(57) ABSTRACT

A composition useful for forming a photoresist layer at i-line (365 nm) comprising (a) a film forming resin; (b) a compound represented by the following formula

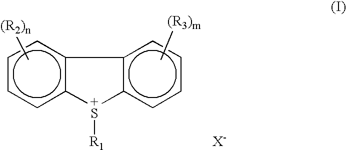

wherein R₁ is a C₁₋₂₀ alkyl group, C₆₋₂₀ aryl group, or C₆₋₂₀ aralkyl group, the C₁₋₂₀ alkyl group, C₆₋₂₀ aryl group, or C₆₋₂₀ aralkyl group being unsubstituted or substituted by one or more groups selected from halogen, C₁₋₂₀ alkyl, C₁₈ perfluoroalkyl, C₁₋₂₀ alkoxy, cyano, hydroxyl, or nitro; R₂ and R₃ are each independently selected from hydrogen, C₁₋₈ alkyl, C₁₋₈ perfluoroalkyl, C₁₋₈ alkoxy, nitro, halogen, carboxyl, hydroxyl, and sulfate; each of m and n are independently 0 or a positive integer; and X⁻ is a non-nucleophilic anion of an acid; (c) optionally, additives to adjust the optical, mechanical and film forming properties; (d) optionally, a base or radiation sensitive base; and (e) a solvent.

### FIELD OF THE INVENTION

The present invention relates to compositions useful for forming a photoresist layer using perfluoroalkyl containing compounds, and more specifically, S-(substituted)dibenzothiophenium salts useful as photoacid generators (PAG).

### BACKGROUND OF THE INVENTION

A polymerization which involves a mechanism of the cationic type has many advantages. In particular, it is fast, even at low temperature, the rate of utilization of the monomer is high and sensitivity towards atmospheric contaminants such as oxygen is low as compared to free radical or anionic polymerizations.

It is known that the preparation in situ of polymerization catalysts has many advantages. The production in situ of an acid which is capable of catalyzing the cross-linking of a monomer enables indeed to prepare a fluid monomer or a prepolymer (thermoplastic or solution) and to give it its final properties, for example by a simple treatment with a radiation. This technique is very much used for inks, paints, adhesive films, photoresists, and anti-adhesive films. It should also be noted that the preparation of the acid in situ from a salt enables in many cases to prevent the storing and handling of acid compounds which are more corrosive than the corresponding salts.

The acid catalysts may be prepared in situ by actinic radiation (such as photons whose wavelength corresponds to ultraviolet, visible, γ and X-ray radiation, ion beam) or by β-radiation (beam electrons) on a suitable salt. Such a salt which is chemically labile under actinic or β-radiation bringing about the release of the corresponding acid with a strong catalytic activity, is a photoinitiator. The advantages of such a process are numerous: the release of the catalyst by radiation is rapid and practically complete, which causes a simultaneous initiation of the growth of the chains, and therefore a more homogeneous distribution of the masses with a lesser polydispersity, and better mechanical properties. The polymerization may be carried out at a relatively low temperature which prevents decomposition or coloring of materials obtained, as well as the formation of bubbles when a solvent is used or when the reaction mixture contains a volatile additive which is intended to be maintained in the final material and which plays the role of plasticizing agent.

Examples of perfluoroalkyl onium salts, useful in photoresists, are discussed in, for example, U.S. Pat. No. 4,250,053, U.S. Pat. No. 5,066,795, U.S. Pat. No. 5,569,771, U.S. Pat. No. 5,863,699, U.S. Pat. No. 6,239,289, U.S. Pat. No. 6,280,987, EP 877293, EP 1275666, JP 05-339261, and J. Amer. Chem. Soc., 115, 2156 (1993).

Photoresists sensitive to short wavelengths, between about 100 nm and about 300 nm are often used where sub-halfmicron geometries are required. Particularly preferred are photoresists comprising non-aromatic polymers, a photoacid generator, optionally a dissolution inhibitor, and solvent.

High resolution, chemically amplified, deep ultraviolet (100-300 nm) positive and negative tone photoresists are available for patterning images with less than quarter micron geometries. To date, there are three major deep ultraviolet (UV) exposure technologies that have provided significant advancement in miniaturization, and these use lasers that emit radiation at 248 nm, 193 nm and 157 nm.

Applicants have now found that certain perfluoroalkyl onium salts useable at lower wavelengths (e.g., 193 nm and 157 nm), can now also be used at longer wavelengths, for example i-line (365 nm). Such a finding is unexpected since most photoresist compositions do not use a chemically amplified system at these wavelengths.

### SUMMARY OF THE INVENTION

The present invention relates to a composition useful for forming a photoresist layer at i-line (365 nm) comprising (a) a film forming resin; (b) a compound represented by the following formula

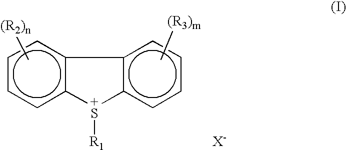

wherein R₁ is a C₁₋₂₀ alkyl group, C₆₋₂₀ aryl group, or C₆₋₂₀ aralkyl group, the C₁₋₂₀ alkyl group, C₆₋₂₀ aryl group, or C₆₋₂₀ aralkyl group being unsubstituted or substituted by one or more groups selected from halogen, C₁₋₂₀ alkyl, C₁₋₈ perfluoroalkyl, C₁₋₂₀ alkoxy, cyano, hydroxyl, or nitro; R₂ and R₃ are each independently selected from hydrogen, C₁₋₈ alkyl, C₁₋₈ alkoxy, nitro, halogen, carboxyl, hydroxyl, and sulfate; each of m and n are independently 0 or a positive integer; and X⁻ is a non-nucleophilic anion of an acid; (c) optionally, additives to adjust the optical, mechanical and film forming properties; (d) optionally, a base or radiation sensitive base; and (e) a solvent in which components (a), (b), (c) and (d) are dissolved to form a clear solution.

For (b), examples of X⁻ include BF₄⁻, CH₃SO₃⁻, CF₃SO₃⁻, CHF₂SO₃⁻, CCl₃SO₃⁻, C₂F₅SO₃⁻, C₂HF₄SO₃⁻, C₄F₉SO₃⁻, (R_{f}SO₂)₃C₋ and (R_{f}SO₂)₂N⁻, wherein each R_{f} is independently selected from the group consisting of highly fluorinated or perfluorinated alkyl or fluorinated aryl radicals and may be cyclic, when a combination of any two R_{f} groups are linked to form a bridge, further, the R_{f} alkyl chains contain from 1-20 carbon atoms and may be straight, branched, or cyclic, such that divalent oxygen, trivalent nitrogen or hexavalent sulfur may interrupt the skeletal chain, further when R_{f} contains a cyclic structure, such structure has 5 or 6 ring members, optionally, 1 or 2 of which are heteroatoms. Examples include (C₂F₅SO₂)₂N⁻, (C₄F₉SO₂)₂N⁻, (C₈F₁₇SO₂)₃C⁻, (CF₃SO₂)₃C⁻, (CF₃SO₂)₂N⁻, (CF₃SO₂)(C₄F₉SO₂)N⁻, (C₂F₅SO₂)₃C⁻, (C₄F₉SO₂)₃C⁻, (CF₃SO₂)₂(C₂F₅SO₂)C⁻, (C₄F₉SO₂)(C₂F₅SO₂)₂C⁻, (CF₃SO₂)(C₄F₉SO₂)N⁻, [(CF₃)₂NC₂F₄SO₂]₂N⁻, (CF₃)₂NC₂F₄SO₂C⁻ (SO₂CF₃)₂, (3,5-bis(CF₃)C₆H₃)SO₂N⁻SO₂CF₃, C₆F₅SO₂C⁻(SO₂CF₃)₂, C₆F₅SO₂N⁻SO₂CF₃,

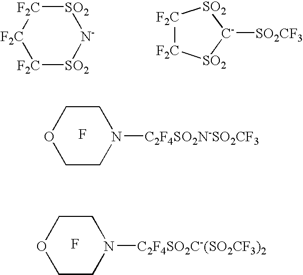

In preferred embodiments for (b), R₁ is a C₁₋₂₀ alkyl group or C₆₋₂₀ aryl group, the C₁₋₂₀ alkyl group or C₆₋₂₀ aryl group being unsubstituted or substituted by one or more groups selected from halogen or C₁₈ perfluoroalkyl and even more preferred embodiments, R₁ is either C₁₋₂₀ alkyl in which all hydrogen atoms have been replaced with fluorine (perfluoroalkyl) or C₆₋₂₀ aryl which is unsubstituted or substituted with trifluoromethyl. In addition, both m and n are both preferably a positive integer and both of R₂ and R₃ are each hydrogen.

Other examples include S-(trifluoromethyl)dibenzothiophenium nonafluorobutanesulfonate, S-(phenyl)dibenzothiophenium nonafluorobutanesulfonate, S-(phenyl)dibenzothiophenium perfluorooctatanesulfonate, S-(3-trifluoromethylphenyl)dibenzothiophenium tetrafluoroborate, S-(4-trifluoromethylphenyl)dibenzothiophenium tetrafluoroborate, S-(1,1,1-trifluoroethyl)dibenzothiophenium trifluoromethylsulfonate, S-(perfluoroethyl)dibenzothiophenium trifluoromethylsulfonate, S-(perfluorobutane)dibenzothiophenium trifluoromethylsulfonate, S-(perfluoroethyl)dibenzothiophenium tetrafluoroborate, S-(perfluorobutane)dibenzothiophenium trifluoromethylsulfonate, and S-(perfluorooctane)dibenzothiophenium trifluoromethylsulfonate.

### DETAILED DESCRIPTION OF THE INVENTION

The present invention relates to a composition useful for forming a photoresist layer at i-line (365 nm) comprising (a) a film forming resin; (b) a compound represented by the following formula

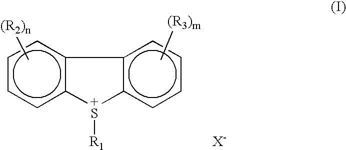

wherein R₁ is a C₁₋₂₀ alkyl group, C₆₋₂₀ aryl group, or C₆₋₂₀ aralkyl group, the C₁₋₂₀ alkyl group, C₆₋₂₀ aryl group, or C₆₋₂₀ aralkyl group being unsubstituted or substituted by one or more groups selected from halogen, C₁₋₂₀ alkyl, C₁₈ perfluoroalkyl, C₁₋₂₀ alkoxy, cyano, hydroxyl, or nitro; R₂ and R₃ are each independently selected from hydrogen, C₁₋₈ alkyl, C₁₋₈ alkoxy, nitro, halogen, carboxyl, hydroxyl, and sulfate; each of m and n are independently 0 or a positive integer; and X⁻ is a non-nucleophilic anion of an acid; (c) optionally, additives to adjust the optical, mechanical and film forming properties; (d) optionally, a base or radiation sensitive base; and (e) a solvent in which components (a), (b), (c) and (d) are dissolved to form a clear solution.

For (b), examples of X⁻ include BF₄, CH₃SO₃⁻, CF₃SO₃, CHF₂SO₃⁻, CCl₃SO₃⁻, C₂F₅SO₃⁻, C₂HF₄SO₃⁻, C₄F₉SO₃⁻, (R_{f}SO₂)₃C⁻ and (R_{f}SO₂)₂N⁻, wherein each R_{f} is independently selected from the group consisting of highly fluorinated or perfluorinated alkyl or fluorinated aryl radicals and may be cyclic, when a combination of any two R_{f} groups are linked to form a bridge, further, the R_{f} alkyl chains contain from 1-20 carbon atoms and may be straight, branched, or cyclic, such that divalent oxygen, trivalent nitrogen or hexavalent sulfur may interrupt the skeletal chain, further when R_{f} contains a cyclic structure, such structure has 5 or 6 ring members, optionally, 1 or 2 of which are heteroatoms. Examples include (C₂F₅SO₂)₂N⁻, (C₄F₉SO₂)₂N⁻, (C₈F₁₇SO₂)₃C⁻, (CF₃SO₂)₃C⁻, (CF₃SO₂)₂N⁻, (CF₃SO₂)(C₄F₉SO₂)N⁻, (C₂F₅SO₂)₃C⁻, (C₄F₉SO₂)₃C⁻, (CF₃SO₂)₂(C₂F₅SO₂)C⁻, (C₄F₉SO₂)(C₂F₅SO₂)₂C⁻, (CF₃SO₂)(C₄F₉SO₂)N⁻, [(CF₃)₂NC₂F₄SO₂]₂N⁻, (CF₃)₂NC₂F₄SO₂C⁻ (SO₂CF₃)₂, (3,5-bis(CF₃)C₆H₃)SO₂N⁻SO₂CF₃, C₆F₅SO₂C⁻(SO₂CF₃)₂, C₆F₅SO₂N⁻SO₂CF₃,

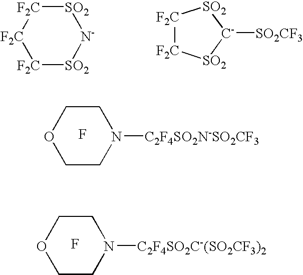

In preferred embodiments for (b), R₁ is a C₁₋₂₀ alkyl group or C₆₋₂₀ aryl group, the C₁₋₂₀ alkyl group or C₆₋₂₀ aryl group being unsubstituted or substituted by one or more groups selected from halogen or C₁₈ perfluoroalkyl and even more preferred embodiments, R₁ is either C₁₋₂₀ alkyl in which all hydrogen atoms have been replaced with fluorine (perfluoroalkyl) or C₆₋₂₀ aryl which is unsubstituted or substituted with trifluoromethyl. In addition, both m and n are both preferably a positive integer and both of R₂ and R₃ are each hydrogen.

When all the hydrogen atoms on, for example, C₁₋₂₀ alkyl group, which can be straight chained or branched, are substituted by a halogen, for example, fluorine, the alkyl group is commonly referred to as “perfluoroalkyl.” Examples of the perfluoroalkyl group having 1 to 20 carbon atoms include trifluoromethyl, perfluoroethyl, n-perfluoropropyl, perfluoroisopropyl, n-perfluorobutyl, sec-perfluorobutyl, tert-perfluorobutyl, n-perfluoropentyl, n-perfluorohexyl, perfluorooctyl, perfluorononyl and perfluorodecyl groups.

Other examples include S-(trifluoromethyl)dibenzothiophenium nonafluorobutanesulfonate, S-(phenyl)dibenzothiophenium nonafluorobutanesulfonate, S-(phenyl)dibenzothiophenium perfluorooctatanesulfonate, S-(3-trifluoromethylphenyl)dibenzothiophenium tetrafluoroborate, S-(4-trifluoromethylphenyl)dibenzothiophenium tetrafluoroborate, S-(1,1,1-trifluoroethyl)dibenzothiophenium trifluoromethylsulfonate, S-(perfluoroethyl)dibenzothiophenium trifluoromethylsulfonate, S-(perfluorobutane)dibenzothiophenium trifluoromethylsulfonate, S-(perfluoroethyl)dibenzothiophenium tetrafluoroborate, S-(perfluorobutane)dibenzothiophenium trifluoromethylsulfonate, and S-(perfluorooctane)dibenzothiophenium trifluoromethylsulfonate.

Photoresist compositions are used in microlithography processes for making miniaturized electronic components such as in the fabrication of computer chips and integrated circuits. Generally, in these processes, a thin coating of film of a photoresist composition is first applied to a substrate material, such as silicon wafers used for making integrated circuits. The coated substrate is then baked to evaporate any solvent in the photoresist composition and to fix the coating onto the substrate. The photoresist coated on the substrate is next subjected to an image-wise exposure to radiation.

The radiation exposure causes a chemical transformation in the exposed areas of the coated surface. Visible light, ultraviolet (UV) light, electron beam and X-ray radiant energy are radiation types commonly used today in microlithographic processes. After this image-wise exposure, the coated substrate is treated with a developer solution to dissolve and remove either the radiation exposed or the unexposed areas of the photoresist. The trend toward the miniaturization of semiconductor devices has led to the use of new photoresists that are sensitive at lower and lower wavelengths of radiation and has also led to the use of sophisticated multilevel systems to overcome difficulties associated with such miniaturization.

There are two types of photoresist compositions: negative-working and positive-working. The type of photoresist used at a particular point in lithographic processing is determined by the design of the semiconductor device. When negative-working photoresist compositions are exposed image-wise to radiation, the areas of the photoresist composition exposed to the radiation become less soluble to a developer solution (e.g. a cross-linking reaction occurs) while the unexposed areas of the photoresist coating remain relatively soluble to such a solution. Thus, treatment of an exposed negative-working resist with a developer causes removal of the non-exposed areas of the photoresist coating and the creation of a negative image in the coating, thereby uncovering a desired portion of the underlying substrate surface on which the photoresist composition was deposited.

On the other hand, when positive-working photoresist compositions are exposed image-wise to radiation, those areas of the photoresist composition exposed to the radiation become more soluble to the developer solution (e.g. a rearrangement reaction occurs) while those areas not exposed remain relatively insoluble to the developer solution. Thus, treatment of an exposed positive-working photoresist with the developer causes removal of the exposed areas of the coating and the creation of a positive image in the photoresist coating. Again, a desired portion of the underlying surface is uncovered.

Photoresist resolution is defined as the smallest feature, which the resist composition can transfer from the photomask to the substrate with a high degree of image edge acuity after exposure and development. In many leading edge manufacturing applications today, photoresist resolution on the order of less than one-half micron are necessary. In addition, it is almost always desirable that the developed photoresist wall profiles be near vertical relative to the substrate. Such demarcations between developed and undeveloped areas of the resist coating translate into accurate pattern transfer of the mask image onto the substrate. This becomes even more critical as the push toward miniaturization reduces the critical dimensions on the devices. In cases where the photoresist dimensions have been reduced to below 150 nanometer (nm), the roughness of the photoresist patterns has become a critical issue. Edge roughness, commonly known as line edge roughness, is typically observed for line and space patterns as roughness along the photoresist line, and for contact holes as side wall roughness. Edge roughness can have adverse effects on the lithographic performance of the photoresist, especially in reducing the critical dimension latitude and also in transferring the line edge roughness of the photoresist to the substrate. Hence, photoresists that minimize edge roughness are highly desirable.

In the present invention, (a) a film forming resin can be those resins typically used for photoresists which are exposed at a variety of wavelengths (e.g., 365 nm and 248 nm). Examples of these resins include novolak resins, resins based on polyhydroxystyrene, and either novolak resins or resins based on polyhydroxystyrene which have been modified with acid labile groups such as acetal, t-BOC, BOCMe, esters, lactones, and the like. Further examples include those acid labile groups and polymers described in U.S. Pat. No. 5,852,128; U.S. Pat. No. 6,458,665; and U.S. Pat. No. 6,486,282, the contents of which are hereby incorporated herein by reference.

Novolak type resins can be prepared by subjecting a phenol or a substituted phenol to an addition-condensation reaction of a phenol or substituted phenol (or a combination thereof) and an aldehyde or ketone (or a combination thereof), in the presence of an acid or a divalent metal salt catalyst, in a suitable reaction solvent, as are well known to one skilled in the art of photoresists. Suitable phenols include, but are not limited to, phenol, chlorophenols, fluorophenols, m-cresol, o-cresol, p-cresol, m-ethyl phenol, o-ethyl phenol, p-ethyl phenol, m-butyl phenol, o-butyl phenol, p-butyl phenol, trimethylsilylphenol, chloromethylphenol, 2,3-xylenol, 2,4-xylenol, 2,5-xylenol, 2,6-xylenol, 3,4-xylenol, 3,5-xylenol, 3,6-xylenol, o-phenyl phenol, m-phenyl phenol, p-phenyl phenol, 2,3,5-trimethylphenol, 2,3,5-triethylphenol, 3,4,5-trimethylphenol, 4-tert-butylphenol, 3-tert-butylphenol, 2-tert-butylphenol, 2-tert-butyl-4-methylphenol, 2-tert-butyl-5-methylphenol and other alkyl-substituted phenols; p-methoxyphenol, m-methoxyphenol, o-methoxyphenol, p-ethoxyphenol, m-ethoxyphenol, o-ethoxyphenol, o-propoxyphenol, p-propoxyphenol, m-propoxyphenol and other alkoxy-substituted phenols; o-isopropenylphenol, p-isopropenylphenol, 2-methyl-4-isopropenylphenol, 2-ethyl-4-isopropenylphenol and other isopropenyl-substituted phenols; phenylphenol and other aryl-substituted phenols; 4,4′-dihydroxybiphenyl, bisphenol A, hydroquinone, resorcinol, 2-methyl resorcinol, 5-methyl resorcinol, pyrogallol, catechol, and other polyhydroxyphenols, as are well known to those skilled in the photoresist art. These phenols may be used either alone or in an admixture of two or more, depending upon the dissolution rate desired.

As for examples of the aldehyde, there may be used, either alone or in combination, those such as formaldehyde, paraformaldehyde, acetaldehyde, benzaldehyde, furfural, trioxane, propionaldehyde, butylaldehyde, trimethylacetaldehyde, acrolein (acrylaldehyde), crotonaldehyde, cyclohexanaldehyde, furylacrolein, terephthalaldehyde, phenylacetaldehyde, α-phenylpropylaldehyde, β-phenylpropylaldehyde, o-hydroxybenzaldehyde, m-hydroxybenzaldehyde, p-hydroxybenzaldehyde, o-methylbenzaldehyde, m-methylbenzaldehyde, p-methylbenzaldehyde, o-chlorobenzaldehyde, m-chlorobenzaldehyde, p-chlorobenzaldehyde, and cinnamaldehyde, and the like.

Examples of the ketones include acetone, methyl ethyl ketone, diethyl ketone and diphenyl ketone. Each of these ketones may be used singly or in combination. Further, an optional combination of any of aldehydes and any of ketones can be employed.

As the acid catalyst, there may be utilized inorganic acids such as hydrochloric acid, nitric acid, sulfuric acid and the like, organic acids such as formic acid, oxalic acid, maleic acid and the like, and divalent inorganic metal salts of copper, cobalt, magnesium, manganese, nickel, zinc and the like. The reaction solvent is normally a hydrophilic solvent, such as methanol or dioxane. Preferred alkali-soluble, film forming novolak resins include phenol-formaldehyde novolaks, cresol-formaldehyde novolaks, and phenol-modified xylenol-formaldehyde novolaks.

As for polyhydroxystyrene based resins, these include o-polyhydroxystyrene, m-polyhydroxystyrene, p-polyhydroxystyrene, hydrogenated polyhydroxystyrene, halogen- or alkyl-substituted polyhydroxystyrene, a hydroxystyrene-N-substituted maleimide copolymer, an o/p- and m/p-hydroxystyrene copolymer, a partial O-alkylated product to the hydroxyl group of polyhydroxystyrene [for example, a 5 to 30 mol % O-methylated product, O-(1-methoxy)ethylated product, O-(1-ethoxy)ethylated product, 0-2-tetrahydropyranylated product, and 0-(t-butoxycarbonyl)methylated product] or O-acylated product [for example, a 5 to 30 mol % o-acetylated product and O-(t-butoxy)carlbonylated product], a styrene-maleic anhydride copolymer, a styrene-hydroxystyrene copolymer, an .alpha.-methylstyrene-hydroxystyrene copolymer, a carboxyl group-containing methacrylic resin and the derivatives thereof, although the invention is not limited to these compounds. Examples of polyhyrdoxystyrene polymers can be found in, for example, U.S. Pat. Nos. 5,807,947 and 5,852,128

For (b), these compounds are generally known, as discussed above. The basic formula is represented by the following formula

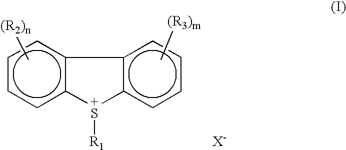

wherein R₁ is a C₁₋₂₀ alkyl group, C₆₋₂₀ aryl group, or C₆₋₂₀ aralkyl group, the C₁₋₂₀ alkyl group, C₆₋₂₀ aryl group, or C₆₋₂₀ aralkyl group being unsubstituted or substituted by one or more groups selected from halogen, C₁₋₂₀ alkyl, C₁₋₈ perfluoroalkyl, C₁₋₂₀ alkoxy, cyano, hydroxyl, or nitro; R₂ and R₃ are each independently selected from hydrogen, C₁₋₈ alkyl, C₁₋₈ alkoxy, nitro, halogen, carboxyl, hydroxyl, and sulfate; each of m and n are independently 0 or a positive integer; and X⁻ is a non-nucleophilic anion of an acid.

Examples of X⁻ include BF₄⁻, CH₃SO₃⁻, CF₃SO₃⁻, CHF₂SO₃⁻, CCl₃SO₃; C₂F₅SO₃⁻, C₂HF₄SO₃⁻, C₄F₉SO₃⁻, (R_{f}SO₂)₃C⁻ and (R_{f}SO₂)₂N⁻, wherein each R_{f} is independently selected from the group consisting of highly fluorinated or perfluorinated alkyl or fluorinated aryl radicals and may be cyclic, when a combination of any two R_{f} groups are linked to form a bridge, further, the R_{f} alkyl chains contain from 1-20 carbon atoms and may be straight, branched, or cyclic, such that divalent oxygen, trivalent nitrogen or hexavalent sulfur may interrupt the skeletal chain, further when R_{f} contains a cyclic structure, such structure has 5 or 6 ring members, optionally, 1 or 2 of which are heteroatoms. Examples include (C₂F₅SO₂)₂N⁻, (C₄F₉SO₂)₂N⁻, (C₈F₁₇SO₂)₃C⁻, (CF₃SO₂)₃C⁻, (CF₃SO₂)₂N⁻, (CF₃SO₂)(C₄F₉SO₂)N⁻, (C₂F₅SO₂)₃C⁻, (C₄F₉SO₂)₃C⁻, (CF₃SO₂)₂(C₂F₅SO₂)C⁻, (C₄F₉SO₂)(C₂F₅SO₂)₂C⁻, (CF₃SO₂)(C₄F₉SO₂)N⁻, [(CF₃)₂NC₂F₄SO₂]₂N⁻, (CF₃)₂NC₂F₄SO₂C⁻ (SO₂CF₃)₂, (3,5-bis(CF₃)C₆H₃)SO₂N⁻SO₂CF₃, C₆F₅SO₂C⁻(SO₂CF₃)₂, C₆F₅SO₂N⁻SO₂CF₃,

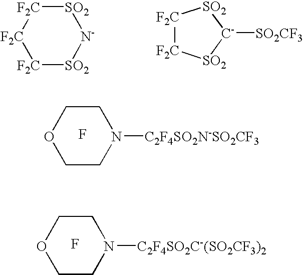

Anions (X⁻) and representative syntheses are described in, e.g., U.S. Pat. Nos. 4,505,997, 5,021,308, 4,387,222, 5,072,040, 5,162,177, 5,273,840, and 5,554,664, incorporated herein by reference, W. M. Lamanna et al., Advances in Resist Technology and Processing XIX, SPIE, Vol. 4690, pp817-828 (2002) and in Turowsky and Seppelt, Inorg. Chem., 27, 2135-2137, (1988). Turowsky and Seppelt describe the direct synthesis of the (CF₃SO₂)₃C⁻ anion from CF₃SO₂F and CH₃MgCl in 20% yield based on CF₃SO₂F (19% based on CH₃MgCl).

Examples of compound (b) include S-(trifluoromethyl)dibenzothiophenium triflate; S-(phenyl)dibenzothiophenium nonafluorobutanesulfonate; S-(trifluoromethyl)dibenzothiophenium nonafluorobutanesulfonate; S-(phenyl)dibenzothiophenium perfluorooctyl sulfonate; S-(3-trifluoromethylphenyl)dibenzothiophenium tetrafluoroborate, S-(4-trifluoromethylphenyl)dibenzothiophenium tetrafluoroborate, S-(perfluoroethyl)dibenzothiophenium triflate, S-(1,1,1-trifluoro-2-ethyl)dibenzothiophenium triflate, S-(perfluorobutyl)dibenzothiophenium triflate, and the like.

The formulation may contain additives denoted as component (c) such as light absorbing agents, dyes, organic carboxylic acids, leveling additives, stabilizing additives, low molecular weight compounds, plasticizing additives, adhesion promoters, surfactants, crosslinkers (e.g., tetramethoxymethyl glycoluril, methylpropyltetramethoxymethyl glycoluril, tetra(ethoxymethyl)glycoluril, tetra(n-propoxymethyl)glycoluril, tetra(i-propoxymethyl)glycoluril, tetra(n-butoxymethyl)glycoluril and tetra(t-butoxymethyl)glycoluril N,N′-dimethyl urea, benzourea, dicyandiamide, formaguanamine, acetoguanamine, ammeline, 2-chloro-4,6-diamino-1,3,5-triazine, 6-methyl-2,4-diamino, 1,3,5-traizine, 3,5-diaminotriazole, triaminopyrimidine, 2-mercapto-4,6-diamino-pyrimidine, 3,4,6-tris(ethylamino)-1,3,5-triazine, tris(alkoxycarbonylamino)triazine, tetramethoxymethylurea tetrahydroxymethylglycoluril, and methylphenyltetramethoxymethyl glycoluril; dialkylol substituted alkyl phenols, and the like, etc), and the like. The type and amount of additives (c) to be used and added will depend upon the type of resist used and the properties desired. The use, type and amount of additives (c) is well within the scope of one of ordinary skill in the art.

Component (d) is a radiation sensitive base or a standard non-radiation sensitive base. Although component (d) is optional, to working resist formulations, its addition is preferred to control the critical dimension of the obtained patterns. Especially use of base compounds can control well the properties of pattern obtained e.g. line width, if the intervals between exposure and post exposure baking is prolonged. In addition, a clear contrast enhancement may be observed. Particularly useful radiation sensitive base compounds suitable as the component (d) include, for example, triphenylsulfonium hydroxide, triphenylsulfonium acetate, triphenylsulfonium phenolate, tris-(4-methylphenyl)sulfonium hydroxide, tris-(4-methylphenyl)sulfonium acetate, tris-(4-methylphenyl)sulfonium phenolate, diphenyliodonium hydroxide, diphenyliodonium acetate, diphenyliodonium phenolate, bis-(4-tert-butylphenyl)iodonium hydroxide, bis-(4-tert-butylphenyl)iodonium acetate, bis-(4-tert-butylphenyl)iodonium phenolate, or the like.

Particularly useful normal base compounds as the component (d) include for example (i) ammonium salts, such as tetramethylammonium hydroxide, tetrabutylammonium hydroxide; (ii) amines, such as n-hexylamine, tridodecylamine, triethanolamine, aniline, dimethylaniline, diphenylamine, triphenylamine, diazabicyclo octane, diazabicyclo undencane; or (iii) basic heterocyclic compounds, such as 3-phenylpyridine, 4-phenylpyridine, lutidine, 2,6-di-tert-butylpyridine, and the like.

The amount of component (d) is determined by the amount and the photoacid generating capabilities of component (b) and varies between about 5 to about 95 mol % to that of component (b). The most preferable amount of component (d) is between about 5 to about 60 mol % with respect to compound (b). This component (d) can also be a mixture of two or more base compounds.

The solvent denoted as component (e) should dissolve components (a), (b), (c) and (d) and is not particularly limited as far as the resist material can be used. The total solid content of the components (a), (b), (c) and (d) may be in the range of from about 1 to about 60% by weight.

Specific examples of the solvent include glycol ethers such as ethylene glycol monomethyl ether, ethylene glycol monoethyl ether, and propylene glycol monomethyl ether, glycol ether acetates such as ethylene glycol monoethyl ether acetate and propylene glycol monomethyl ether acetate (PGMEA), esters such as ethyl lactate, ketones such as acetone, methyl ethyl ketone, cyclopentanone, cyclohexanone or cycloheptanone, lactones, such as γ-valerolactone, and less preferred aromatic hydrocarbons, such as toluene and xylene. In some cases, acetonitrile, dimethylformamide, dioxane, and the like may also be used. These solvents (e) may be used alone or in the form of a mixture of two or more.

The present invention also is directed to a method of forming a pattern using the photosensitive composition of this invention. First, the composition of the present invention is coated on the surface of a predetermined substrate by spin coating, spray coating, dip coating or other methods well known to those skilled in the art. Then, the coated layer is the pre-baked (prior to exposure to actinic radiation) at a temperature of about 200° C. or less, or preferably at a temperature of about 70 to about 120° C. thereby forming a resist film. The substrate to be used in this case may be, for example, a silicon wafer; a silicon wafer provided thereon with various kinds of insulating films, electrodes or interconnecting wirings; a blank mask; etc.

Then, the resist film is irradiated through a predetermined mask pattern by an actinic radiation, or directly scanned by an actinic radiation, thereby performing the light exposure of the resist film.

The resist film thus pattern-exposed is then subjected to a heat treatment (post-exposure baking) generally at a temperature within the range from about 50 to about 180° C., preferably from about 60 to about 120° C., by means of heating over a heated plate or oven, or by means of infra-red irradiation. According to such a heat treatment, in the light exposure portion of the resist film, an acid generated by the light exposure functions as a catalyst and is allowed to react with a compound having a substituent which is decomposed by the acid. In this case, if the temperature of the heat treatment is less than about 50° C., it becomes difficult to sufficiently cause the reaction between the acid generated by the photo-acid generator and the compound having a substituent which is decomposed by an acid. On the other hand, if the temperature exceeds about 180° C., the excess decomposition or curing are likely to arise over both the light exposure portion and non-exposure portion of the resist film.

Thus, regarding the compound a substituent which is decomposed by an acid, the substituent is decomposed to exhibit the alkali-solubility. Sometimes, the same effect as that obtained by the baking after the light exposure can be obtained by standing at room temperature for a sufficient long time.

Subsequently, the resist film thus baked is then subjected to a developing treatment by making use of a dipping method, a spraying method or a puddle method, thereby selectively dissolving and removing the light exposure portion of the resist film in the case of a positive resist or selectively dissolving and removing the non-exposed portion of the resist film in the case of a negative resist to obtain a desired pattern. The alkaline solution can be preferably used in this case as the developer. Examples of such an alkaline solution are inorganic alkaline solutions such as aqueous solutions of sodium hydroxide, sodium carbonate, sodium silicate and sodium metasilicate; organic alkaline solutions such as aqueous solutions of tetramethylammonium hydroxide and trimethylhydroxyethylammonium hydroxide; and those obtained by adding alcohols and a surfactant to them. These alkaline solutions are used in general at the concentration of 15% by weight or less in view of sufficiently differentiate the dissolution rate of the light exposure portion from that of the non-exposure portion. The developed substrate and resist film (resist pattern) are subjected to a rinsing treatment using water optionally, and then dried.

### EXAMPLES

### Example 1

Synthesis of S-(trifluoromethyl)dibenzothiophenium nonafluorobutanesulfonate

A suspension was prepared of S-(trifluoromethyl)dibenzothiophenium tetrafluoroborate (2.0 g, 5.88 mmol.) in 5 ml of ethyl acetate in an Erlenmeyer flask. To this suspension was added a suspension of 3.978 g potassium nonaflate in 10 ml of distilled water. The mixture was stirred rapidly a with magnetic stir bar for 2 days. After this time, the two phase mixture was diluted with 20 ml of ethyl acetate, and filtered to remove excess potassium nonaflate. The aqueous layer was removed from the ethyl acetate and the latter was washed with five 20 ml aliquots of distilled water in a separatory funnel. The washed ethyl acetate solvent was then stripped of most of the solvent on a roto-evaporator and further dried in a vacuum oven overnight to remove residual water. The dried residue was then recrystallized three times in a mixture of hexane and ethyl acetate. In this manner 2.67 g of pure S-(trifluoromethyl)dibenzothiophenium nonafluorobutanesulfonate was recovered (91% yield) which was pure as determined by elemental analysis (Expected: C:36.97, H:1.46, F:41.27, S:11.10 Found: C:36.77, H:1.44, F:41.46, S:11.44; Boron analysis<0.01%).

### Example 2

Positive i-line Resist Formulation:

The following wt. percentages of resist components were dissolved in PGMEA to prepare a resist solution of 36.48% solids suitable for producing 10 μm thick films spun coated on wafers.

| Polymer: PHS 602020¹ | | 95.764% |
|---|---|---|
| PAG from Example 1 | | 1.957% |
| Bases: | 1) tridodecylamine | 0.1164% |
| | 2) triethanolamine | 0.1354% |

| | |
|---|---|
| Adhesion promoter: low Tg resin | 2.03% |
| Surfactant² | 0.02% |

¹The polymer is a ter-polymer of 60% hydroxystyrene, 20% styrene and 20% t-butylacrylate (from DuPont Electronic Polymers, Texas).
²an example is a fluorosurfactant (Megaface R8 from Dianippon Ink)

Processing and Results:

A wafer was spin coated with the formulation of Example 2. The coated wafer was baked at 120° C. for 2 minutes, exposed to patterned i-line radiation, post exposure baked at 110° C. for 60 seconds then developed for 60 seconds in MIF-300 developer (Clariant Corporation). The resist resolved 3 μm features with high aspect ratio, vertical sidewall profiles and sharp edges. The photospeed of the resist is 60 mJ/cm²

### Example 3

Negative Resist Formulation:

The following wt. percentages of resist components were dissolved in PGMEA to prepare a resist solution of 30% solids suitable for producing 2 μm thick films spun coated on wafers.

| m-Cresol novolak resin | | 76.53% |
|---|---|---|
| PAG from Example 1 | | 3.04% |
| Crosslinkers: | 1) Powderlink | 17.80% |
| | 2) DML-POP³ | 2.40% |

| | |
|---|---|
| Base: triethanolamine | 0.227% |

³DML-POP is a dimethylol-alkyl substituted phenol (Honshu Chemical Co.)

Processing and Results:

A wafer was coated with the formulation from Example 3. The coated wafer was baked at 110° C. for 60 seconds, exposed to patterned i-line radiation, post exposure baked at 110° C. for 60 seconds, then developed for 120 seconds in MIF-300 developer (Clariant Corporation). The resist resolved 1 μm features with steep sidewall profiles at 70 mJ/cm².

### Example 4

Negative Resist Formulation:

The following wt. percentages of resist components were dissolved in PGMEA to prepare a resist solution of 30% solids suitable for producing 2 μm thick films spun coated on wafers.

| | |
|---|---|
| Shonol CKS-670 resin⁴ | 75.6% |
| PAG from Example 1 | 5.00% |
| Crosslinker: 1) Powderlink | 18.90% |
| Surfactant | 0.065% |
| Base | 0.397% |

⁴Phenolic resin from Showa Highpolymer, Japan.

Processing and Results:

A wafer was coated with the formulation from Example 4. The coated wafer was baked at 110° C. for 60 seconds, exposed to patterned i-line radiation, post exposure baked at 110° C. for 60 seconds, then developed for 120 seconds in MIF-300 developer (Clariant Corporation). The resist resolved 1 μm features with steep sidewall profiles at 70 mJ/cm²

The foregoing description of the invention illustrates and describes the present invention. Additionally, the disclosure shows and describes only the preferred embodiments of the invention but, as mentioned above, it is to be understood that the invention is capable of use in various other combinations, modifications, and environments and is capable of changes or modifications within the scope of the inventive concept as expressed herein, commensurate with the above teachings and/or the skill or knowledge of the relevant art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

We claim:

1. A composition useful for forming a photoresist layer at i-line (356 nm) comprising (a) a film forming resin; (b) a compound represented by the following formula 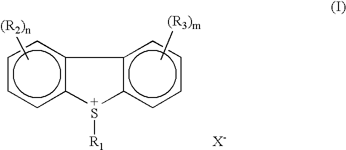
wherein R₁ is a C₁₋₂₀ alkyl group, C₆₋₂₀ aryl group, or C₆₋₂₀ aralkyl group, the C₁₋₂₀ alkyl group, C₆₋₂₀ aryl group, or C₆₋₂₀ aralkyl group being unsubstituted or substituted by one or more groups selected from halogen, C₁₋₂₀ alkyl, C₁₋₈ perfluoroalkyl, C₁₋₂₀ alkoxy, cyano, hydroxyl, or nitro; R₂ and R₃ are each independently selected from hydrogen, C₁₋₈ alkyl, C₁₋₈ perfluoroalkyl, C₁₋₈ alkoxy, nitro, halogen, carboxyl, hydroxyl, and sulfate; each of m and n are independently 0 or a positive integer; and X⁻ is a non-nucleophilic anion of an acid; (c) optionally, additives to adjust the optical, mechanical and film forming properties; (d) optionally, a base or radiation sensitive base; and (e) a solvent in which components (a), (b), (c) and (d) are dissolved to form a clear solution.

2. The composition of claim 1 wherein X⁻ is BF₄, CH₃SO₃, CF₃SO₃; CHF₂SO₃⁻, CCl₃SO₃⁻, C₂F₅SO₃⁻, C₂HF₄SO₃⁻, C₄F₉SO₃⁻, (C₂F₅SO₂)₂N⁻, (C₄F₉SO₂)₂N⁻, (C₈F₁₇SO₂)₃C⁻, (CF₃SO₂)₃C⁻, (CF₃SO₂)₂N⁻, (CF₃SO₂)(C₄F₉SO₂)N⁻, (C₂F₅SO₂)₃C⁻, (C₄F₉SO₂)₃C⁻, (CF₃SO₂)₂(C₂F₅SO₂)C⁻, (C₄F₉SO₂)(C₂F₅SO₂)₂C⁻, (CF₃SO₂)(C₄F₉SO₂)N⁻, [(CF₃)₂NC₂F₄SO₂]₂N⁻, (CF₃)₂NC₂F₄SO₂C⁻(SO₂CF₃)₂, (3,5-bis(CF₃)C₆H₃)SO₂N⁻SO₂CF₃, C₆F₅SO₂C⁻(SO₂CF₃)₂, C₆F₅SO₂N⁻SO₂CF₃,

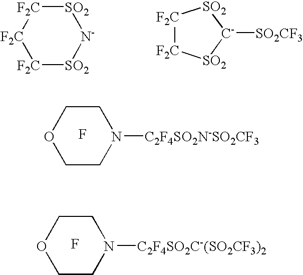

3. The composition of claim 2 wherein R₁ is a C₁₋₂₀ alkyl group or C₆₋₂₀ aryl group, the C₁₋₂₀ alkyl group or C₆₋₂₀ aralkyl group being unsubstituted or substituted by one or more groups selected from halogen and C₁₋₈ perfluoroalkyl, and R₂ and R₃ are each independently selected from hydrogen.

4. The composition of claim 3 wherein R₁ is a C₁₋₂₀ alkyl group substituted by one or more halogen groups.

5. The composition of claim 3 wherein R₁ is a C₆₋₂₀ aryl group, the C₆₋₂₀ aryl group being unsubstituted or substituted by C₁₋₈ perfluoroalkyl.
A. The composition of claim 1 wherein (a) film forming resin is selected from novolaks, resins based on polyhydroxystyrene and novolak polyhydroxystyrene based resins which have been modified with acid labile groups.

6. A method of forming a pattern comprising the steps of:
(i) forming a photosensitive layer on a substrate, the photosensitive layer containing as a main component the photosensitive composition according to claim 1;
(ii) selectively exposing a predetermined region of the photosensitive layer to a chemical radiation;
(iii) applying a baking treatment to the photosensitive layer after the exposure to chemical radiation; and
(iv) developing the photosensitive layer after the baking treatment so as to selectively remove the predetermined region of the photosensitive layer.

7. A method for forming a pattern, which comprises the steps of:
(i) coating the photosensitive composition of claim 1 on a substrate, and drying the photosensitive composition with heating thereby forming a resin layer;
(ii) exposing a predetermined area of said resin layer to a pattern exposure by means of light irradiation;
(iii) performing a heat treatment of said resin layer after the pattern exposure; and
(iv) developing said resin layer after the heat treatment by using a developer
